(19) United States
(12) Patent Application Publication
(10) Pub. No.: US 2025/0329605 A1
(43) Pub. Date: Oct. 23, 2025

(54) THERMAL SUBSTRATE

(71) Applicant: Advanced Diamond Holdings, LLC, Beltsville, MD (US)

(72) Inventor: John P. Ciraldo, Clarksburg, MD (US)

(21) Appl. No.: 19/183,814

(22) Filed: Apr. 19, 2025

Related U.S. Application Data
(60) Provisional application No. 63/636,658, filed on Apr. 19, 2024.

(51) Int. Cl. H01L 23/373; C30B 25/20; C30B 29/04; C30B 33/00; H01L 21/02; H01L 21/3105; H01L 21/48

(52) U.S. Cl. CPC H01L 23/3732; C30B 25/20; C30B 29/04; C30B 33/00; H01L 21/02115; H01L 21/02271; H01L 21/31051; H01L 21/4871

(57) ABSTRACT

A diamond thermal structure includes a diamond heat spreader layer that has been enriched in carbon-12 isotope, and a diamond thermal sink layer positioned beneath the heat spreader. The thermal sink layer contains diamond with a non-enriched isotopic composition.

### PRIORITY

This patent application claims priority from provisional U.S. patent application No. 63/636,658, filed Apr. 19, 2024, entitled, “THERMAL SUBSTRATE,” and naming John P. Ciraldo as inventor, the disclosure of which is incorporated herein, in its entirety, by reference.

### FIELD OF THE INVENTION

Illustrative embodiments generally relate to thermal management in semiconductor devices and, more particularly, illustrative embodiments relate to integrated circuits that incorporate diamond-based substrates,.

### BACKGROUND OF THE INVENTION

Thermal management of integrated circuits (ICs) is significant for several reasons, primarily related to the physical properties of the materials involved and the operational reliability and efficiency of the devices. When ICs operate, they consume electrical power, a portion of which is converted into heat due to the resistance in the materials and the switching activities of transistors. This is particularly pronounced in high-performance devices like CPUs, GPUs, and high-speed memory, where billions of transistors switch on and off billions of times per second. Excessive heat can lead to thermal stress on the materials in the IC, potentially causing physical damage or degradation over time. Materials expand when heated and contract when cooled; repeated thermal cycling can cause fatigue in the materials, leading to cracks and other failures. High temperatures can also accelerate electromigration, a process that gradually degrades the pathways in the chip. Many semiconductor materials, including silicon, have properties that vary with temperature.

### SUMMARY

In accordance with an embodiment, a diamond thermal structure includes a diamond heat spreader layer that has been enriched in carbon-12 isotope, and a diamond thermal sink layer positioned beneath the heat spreader. The thermal sink layer contains diamond with a non-enriched isotopic composition.

In various embodiments, the carbon-12 atomic concentration in the heat spreader may equal or exceed 99.5%. The thickness of the heat spreader layer may range from 1 micron to 20 microns. The thermal sink layer may have a carbon isotope ratio substantially matching that of methane found in nature. The heat spreader and thermal sink may be deposited in a continuous chemical vapor deposition process, switching gases without stopping deposition. Alternatively, the structure may be formed by growing the heat spreader on a polished substrate, then growing the thermal sink atop the spreader, followed by separation from the substrate to expose the heat spreader at the top.

In some embodiments, the composite structure also includes a wide bandgap or ultra-wide bandgap semiconductor device thermally coupled to the top surface of the diamond heat spreader.

In accordance with another embodiment, A method of fabricating a diamond thermal structure deposits a diamond heat spreader layer on a substrate using a carbon-containing precursor gas enriched in carbon-12. The method continues by switching to a carbon-containing gas with an unenriched isotopic mix, and then depositing a thermal sink layer atop the heat spreader. After deposition, the diamond structure is separated from the substrate to expose the heat spreader.

The enriched precursor gas may have a carbon-12 concentration equal to or greater than 99.5%. The heat spreader layer may be grown to a thickness between 1 and 20 microns. The entire process can be performed in a continuous CVD system without breaking vacuum. The substrate may be made of single-crystal or polycrystalline diamond, and separation may be achieved using laser cleaving, ion implantation, or a sacrificial release layer. The separated structure may be flipped to position the heat spreader at the top surface, which may optionally be polished to prepare for bonding to a semiconductor device.

A method of fabricating the diamond thermal structure begins with depositing a thermal sink layer on a substrate using a non-enriched carbon-containing gas. The surface of the thermal sink is then polished, and a heat spreader layer is deposited using a precursor gas enriched in carbon-12.

In this forward process, the enriched precursor gas may include more than 99% carbon-12. Preferably, greater than 99.5% carbon-12. The heat spreader may be between 1 and 20 microns thick. Both the thermal sink and spreader layers can be deposited via chemical vapor deposition. The polishing process may achieve a surface roughness of less than 10 nanometers RMS. Suitable substrates may include diamond, silicon, sapphire, or silicon carbide. After depositing the heat spreader, its surface may also be polished to enable bonding. The layers may be bonded directly without an intermediate adhesion layer.

An integrated circuit includes a wide bandgap or ultra-wide bandgap semiconductor device that generates heat. This device is coupled to a C12-enriched diamond heat spreader, which in turn is connected to a diamond heat sink having a natural isotopic composition of C12 and C13.

In some cases, the heat spreader is thermally connected at the heat-generating portion of the device. The heat spreader and heat sink may be either grown together or bonded. The heat spreader may have a thickness that is 10% or less of the heat sink layer. The semiconductor device may be a transistor. In addition, the structure may include a larger metal heat sink thermally connected to the diamond heat sink. This secondary heat sink may include fins and be made from copper or other conductive metals.

In accordance with yet another embodiment, a method dissipates heat from an electronic device by growing a diamond substrate in a CVD chamber. The process first grows a diamond heat sink layer using a carbon source with one concentration of C12, followed by growth of a heat spreader layer using a source with a higher C12 concentration. The spreader is then thermally coupled to an electronic device.

This method may include attaching the diamond heat sink to a non-diamond heat sink, such as a copper structure. Heat is generated in the device at a specific region, and transferred into the heat spreader and then the sink. The heat sink may be 50 to 1200 microns thick, more typically 100 to 550 microns. The heat spreader may be 50 nm to 50 microns thick, more typically 1 to 50 microns, and may have a thickness less than 25-33% of the total diamond structure.

The method may be applied to transistors or other devices. Another embodiment includes providing a diamond structure with two surfaces, where the surface touching the electronic device contains a higher concentration of C12 than the opposite side. The device may again be a transistor, and may be paired with a large external heat sink.

Additional embodiments may involve multiple devices or doped junctions, and may be used in high-frequency and high-power systems. Gate sizes of the devices may range from 100 nm to 5 microns. Devices using the disclosed structure may achieve energy densities between 2 W/mm and 20 W/mm. The heat spreader layer may have C12 isotopic purity of at least 99.9%, as measured by mass spectrometry.

### BRIEF DESCRIPTION OF THE DRAWINGS

Those skilled in the art should more fully appreciate advantages of various embodiments of the invention from the following “Description of Illustrative Embodiments,” discussed with reference to the drawings summarized immediately below.

FIG. 1 schematically shows an integrated circuit (IC), also known as a microchip or just a chip in accordance with illustrative embodiments

FIG. 2A schematically shows a detailed side view of the heat generating portion of the device relative to the heat spreading portion in accordance with illustrative embodiments.

FIG. 2B schematically shows a top view of FIG. 2A in accordance with illustrative embodiments.

FIG. 2C schematically shows a top view of the heat generating portion of the device relative to the heat spreading portion in accordance with illustrative embodiments.

FIG. 3A schematically shows a heat spreading portion having a surface area that is substantially the same as the size of the gate in accordance with illustrative embodiments.

FIG. 3B-3C schematically show a plurality of devices on a single substrate in accordance with illustrative embodiments.

FIG. 4 schematically shows the integrated device coupled to a large heat sink (e.g., a non-diamond heat sink) in accordance with illustrative embodiments.

FIG. 5 schematically shows a process of fabricating a diamond-based heat spreading substrate in accordance with illustrative embodiments of the invention.

FIG. 6 schematically shows a variance in the thickness of the diamond layers in accordance with illustrative embodiments.

FIG. 7 schematically shows a top diamond layer in accordance with illustrative embodiments.

### DESCRIPTION OF ILLUSTRATIVE EMBODIMENTS

Illustrative embodiments provide a thermal substrate for integrated circuits, featuring a dual-layer diamond structure that enhances heat management in high-power and high-frequency semiconductor devices. The system integrates an ultra-high thermal conductivity heat spreader composed of isotopically pure Carbon-12 (C12) diamond directly beneath the heat-generating regions of the chip, such as GaN transistor gates, to laterally distribute heat and mitigate thermal hotspots. Beneath this, a more economical diamond heat sink layer—having isotopically standard or isotopically unpure diamond (C12/C13)—provides bulk thermal dissipation. Grown monolithically or bonded together using chemical vapor deposition (CVD), the layered diamond substrate enables improved device cooling, increased energy density, and reduced footprint, with applications in RF electronics, power conversion, and aerospace systems.

In illustrative embodiments, diamond and gallium nitride (GaN) are combined in high-power electronic and optoelectronic devices primarily to enhance thermal management. GaN has high electron mobility and ability to operate at high temperatures and voltages, making it suitable for, among other things, high-performance transistors, LEDs, and laser diodes. However, GaN devices generate significant amounts of heat, which can affect performance and reliability. Diamond has an exceptionally high thermal conductivity, which makes it an ideal material to draw heat away from the GaN components. By integrating a diamond layer, either as a substrate or a heat spreader, the heat generated by the GaN can be efficiently dissipated. This helps in maintaining the operational temperature of the GaN device within safe limits, thereby enhancing performance and extending the lifespan of the device.

Growing diamond on GaN can be challenging due to lattice mismatch and different thermal expansion coefficients between diamond and GaN. Thus, various embodiments may grow buffer layers between the diamond and the GaN to help manage the lattice mismatch and ensure a better mechanical and thermal connection. Materials like aluminum nitride (AlN) may be used as buffer layers. However, the use of the buffer lay undesirably reduces the ability of the diamond to conduct heat from the GaN.

Some other embodiments may bond diamond heat spreaders to GaN devices. This is simpler than integrating diamond as a substrate and can be retrofitted to existing designs. GaN devices are grown on a foreign substrate, the substrate may be thinned out and bonded to the diamond for heat conduction.

Some embodiments may use thin diamond films deposited onto GaN devices, though this method might not provide as efficient thermal conductivity as thicker, bulk diamond.

In illustrative embodiments, diamond is advantageously made highly thermally conductive by controlling the isotope of the diamond. The highly thermally conductive diamond functions as a heat spreader. The heat spreader conducts heat away from the chip (e.g., the GaN) itself. Since C12 diamond is highly thermal conductivity, it is effective at quickly absorbing and spreading out the heat. By spreading the heat across a larger area, the C12 heat spreader helps in more effective heat dissipation. The heat spreader acts as the interface between the chip and any additional cooling mechanisms, such as heatsinks or liquid cooling systems. It ensures that heat is evenly transferred to these cooling solutions. In various embodiments the diamond also protects the delicate GaN of the chip from physical damage and from direct contact with the cooling solutions, which might otherwise cause stress or damage due to uneven surfaces or pressure. Illustrative embodiments are discussed below.

Carbon has two stable isotopes and several radioactive isotopes. The two stable isotopes are Carbon-12 (C12) and Carbon-13 (C13). Natural diamonds are primarily composed of the carbon-12 (C12) isotope, which is the most abundant isotope of carbon, constituting about 98.9% of all carbon in nature. Because of this predominance, carbon-12 is also the major component of all naturally occurring organic compounds, including diamond.

Carbon-13 (C13) is also present in diamonds, but in much smaller amounts, reflecting its overall natural abundance of about 1.1%. The specific ratio of carbon-12 to carbon-13 in a diamond can vary slightly based on the diamond's origin and the carbon sources from which it was formed. This ratio is sometimes used by geologists to trace the processes and origins of diamonds, as different types of organic materials and geological processes can leave distinct carbon isotopic signatures.

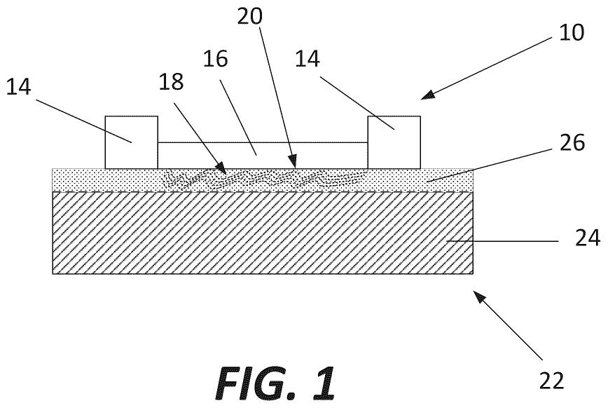

FIG. 1 schematically shows an integrated circuit (IC), also known as a microchip or just a chip in accordance with illustrative embodiments. The IC is a tiny electronic device made out of a small piece of semiconductor material, usually silicon, GaN, etc. On this small chip, thousands, millions, or even billions of electrical devices like transistors, diodes, resistors, and capacitors are fabricated closely together. These devices are interconnected to perform various electronic functions such as amplifying signals, computing, or storing data.

For simplicity, FIG. 1 shows a single device 10, for example, a transistor on a substrate 22 in accordance with illustrative embodiments. The transistor may have a source contact 14, a drain contact 14, and a gate 16. Most of the heat 18 in a transistor is generated in the region 20 between the source 14 and the drain, 15 known as the gate 16. The area where heat is generated may be referred to as a heat generating area 20 or a heat generating portion 20. Other devices also have heat generating areas 20. For example, in a diode, most of the heat 18 is generated at the junction where the p-type and n-type semiconductor materials meet. In a resistor, heat 18 is primarily generated throughout the body of the resistor itself. Those skilled in the art can determine heat generating areas of various devices.

In illustrative embodiments, the one or more devices 10 are on a diamond substrate 22. Although the substrate 22 may be relatively large, a heat spreader portion 26 (also referred to as the heat spreader 26) of the substrate 22 is adjacent to the heat generating area 20 of the device 10. Various embodiments provide a C12 heat spreading portion 26 underneath the heat generating portion 20. Then, the remainder of the diamond substrate 22 may be a combination of C12 and C13 that operates as a bulk heat sink portion 24 (also referred to as the heat sink 24 or substrate-level heat sink 24). Thus, heat 18 from the relatively small heat generating area 20 is spread across a larger heat spreading portion 26, which pulls the heat towards a larger heat sink portion 24.

C12 isotopically pure diamond can be expensive to manufacture. Accordingly, illustrative embodiments provide C12 diamond in the heat spreading portion 26.

To create isotopically pure diamond, isotopically pure methane gas may be used. Illustrative embodiments may thus grow diamond in a CVD chamber using regular methane gas. At some point during the growth process, when it is desirable to grow isotopically pure C12 diamond, an isotopically pure methane gas may be used. In various embodiments, the heat sink 24 may be grown to hundreds of microns of thickness, and typically 100-550 microns. In various embodiments, the heat spreading film 26 may be 1-50 microns on top of the heat sink portion 24, although the final thickness is dependent on the features applied. The films 26 do not be require additional treatments, such as is the case in quantum applications, due to them being used only as a passive heat spreader 26. Various embodiments grow the diamond heat spreader 26 using isotopically pure methane gas. Optionally, pressure, nitrogen concentration, and growth conditions may otherwise remain substantially the same when growing the heat spreader 26 and when growing the heat sink 24.

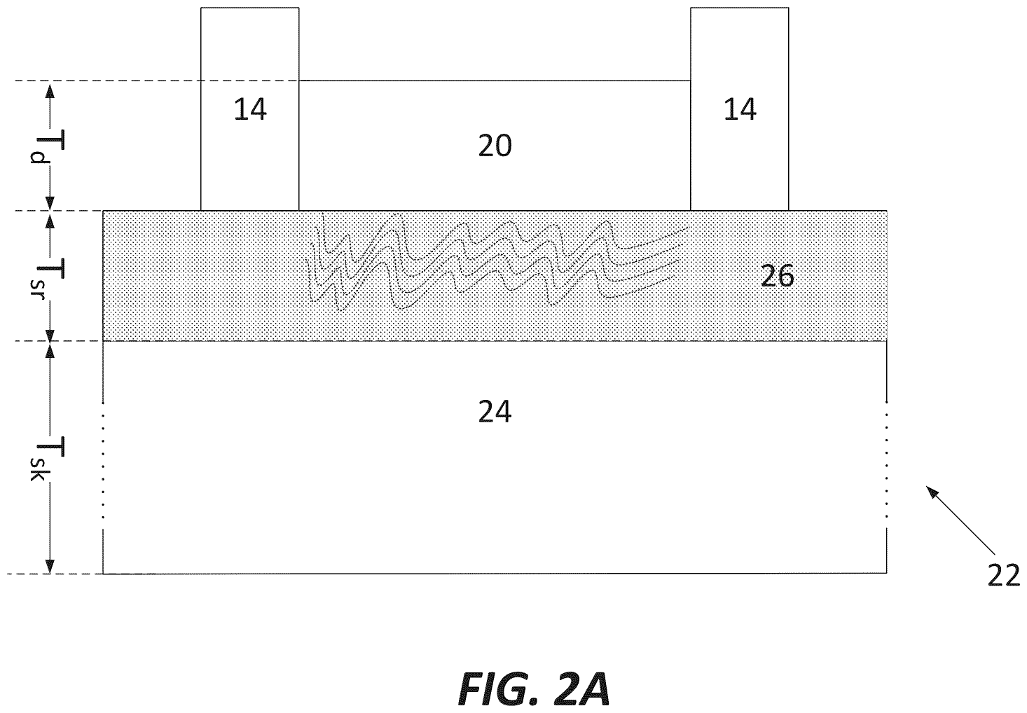

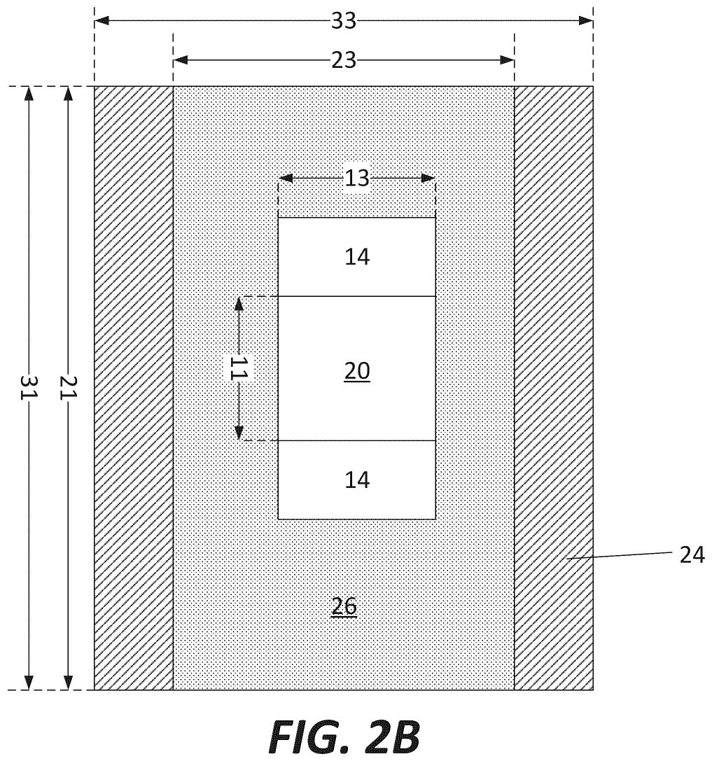

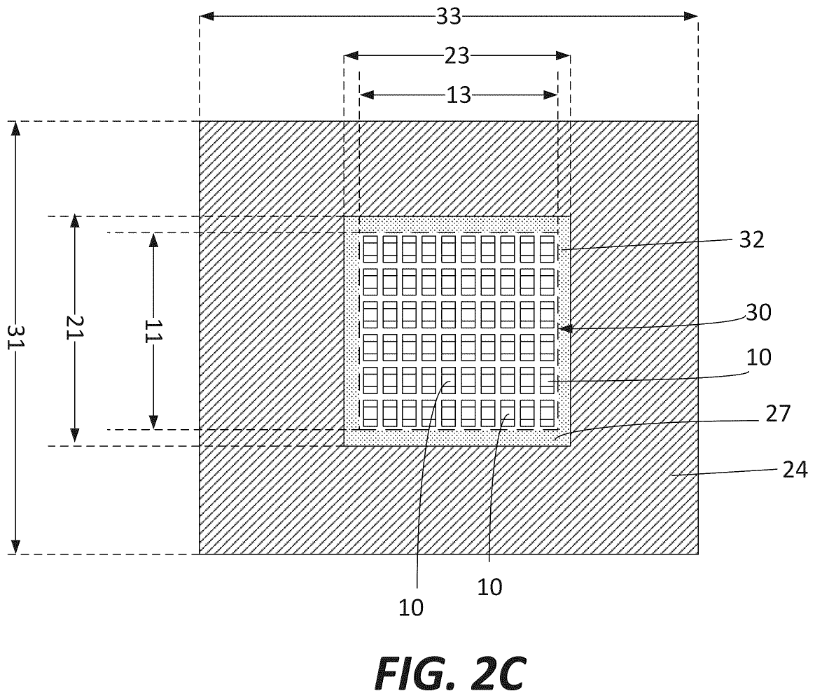

FIG. 2A schematically shows a detailed side view of the heat generating portion 20 of the device 10 relative to the heat spreading portion 26 in accordance with illustrative embodiments. In various the heat spreading portion 26 has a thickness that is proportional to the heat generating portion 20 (e.g., the gate 16 size). This allows a thin film of C12 at the top surface that has excellent heat extraction throughout the substrate 22. The substrate 22 thus advantageously acts very similar to a substrate 22 formed entirely of C12 without the expense of fabricating the entire substrate 22 of C12.

In some embodiments, R=thickness of the heat generating portion 20 of the device (Td) (e.g., the thickness of the gate). In various embodiments, the heat spreading portion 26 may have a thickness (Tsr) of between about R and about R\hat{ }2. In general, the thickness of the heat sink portion 24 (Tsk) is greater than the thickness of the heat spreading portion 26 (Tsr). In various embodiments, the heat sink portion 24 may be between about 100-550 microns thick. Some embodiments may be as thin as 50 microns.

FIG. 2B schematically shows a top view of FIG. 2A in accordance with illustrative embodiments. The heat spreader 26, heat sink 24, and heat generating portion 20 may all be considered to have an area defined by a length multiplied by a width. This is not intended to imply that the area must be rectangular, but merely is shown for discussion purposes. In some other embodiments, the area may include a radius, or may be defined by other dimensions (e.g., of a non-regular shape). Any of the aforementioned areas may have a rectangular or non-rectangular shape.

The area of the heat spreader 26 is generally the same as or larger than the area of the heat-generating portion 20 it is designed to cool. In various embodiments, the heat generating portion 20 can be said to have an area roughly defined by a length 11 and a width 13. When there are multiple devices 10 having multiple heat generating portions 20, the area of the heat spreading portion 26 is generally larger than the sum of the area of the heat generating portions 20. The area of the heat sink 24 is generally the same as or larger than the area of the heat spreader 26. The heat spreader 26 has an area (particularly for a top surface that interfaces with the heat generating portion(s) 20) that is defined by a length 21 and width 23. In a similar manner, the heat sink 24 has an area (particularly for a top surface that interfaces with the heat spreader 26) that is defined by a length 31 and a width 33.

Thus, various embodiments advantageously provide a C12 pure heat spreader 26 that distributes heat across its surface. The heat spreader 26 has a given isotopic purity (i.e., the proportion of a particular isotope (in this case, Carbon-12) relative to all other carbon isotopes present in the material). As described herein, the heat spreader 26 can be considered C12 pure if it is equal to or greater than 99.5% isotopic purity. In various embodiments, the heat spreader 26 has greater than 99.8%, or greater than 99.9% C12 isotopic purity. Indeed, various embodiments achieve greater than 99.95% C12 isotopic purity for the heat spreader 26. Various embodiments could, in theory, form the heat spreader 26 from isotopically 100% pure C12 diamond to achieve optimal thermal conductivity. However, due to current practical manufacturing limitations, such levels of purity are not yet widely achievable at scale. Illustrative embodiments are not intended to be limited by current manufacturability, and in some embodiments, upper isotopic purities may range up to approximately 99.998% C12, depending on available deposition and purification technologies.

This ratio can be measured using mass spectrometry techniques, including ToF SIMS. This helps in managing hot spots on the chip that generate more heat, thus preventing any single point from becoming excessively hot. In various embodiments, the heat spreader 26 is advantageously formed from a higher concentration of C12 diamond (than the remainder of the diamond) that has excellent high thermal conductivity, to facilitate quick heat distribution. The heat spreader 26 is directly in contact with the heat-generating component, like the heat generating portion 20, and acts as the first level of heat distribution. The heat spreader 26 spreads out the heat generated by the chip to a larger area, making it easier for the subsequent cooling mechanisms (like the heat sink 24) to dissipate this heat effectively.

Furthermore, illustrative embodiments provide a monolithically grown diamond heat sink 24 with the heat spreader 26. The heat sink 24 dissipates heat into the surrounding environment, typically the air inside the casing of the device or directly to a cooling fluid in more advanced systems. The heat sink 24 is formed of a lower concentration of C12 diamond than the heat spreader 26 (e.g., diamond that may include C12 and C13, and is advantageously more economical), which increase the surface area that interacts with the air or cooling medium. The heat sink 24 is advantageously grown on the heat spreader 26 (or vice versa) using, for example, CVD. In some other embodiments, the heat sink 24 may be otherwise attached to or placed on top of the heat spreader 26. In some embodiments, the heat sink 24 can be part of a more complex cooling system that includes fans, heat pipes, or liquid cooling loops. By maximizing the surface area exposed to air (or another coolant), the diamond heat sink 24 enables efficient heat transfer from the electronic component to the environment, thus cooling the component. While the heat spreader 26 evenly distributes the heat from the chip, the heat sink 24 removes this heat by allowing it to dissipate into the environment.

Illustrative embodiments advantageously allow for improved heat management, and therefore, for smaller devices. In various embodiments, the size of the transistor may be reduced relative to current state of the art transistors. The devices may be used for high-power high-frequency applications. This includes applications where there is a wide bandgap (e.g. GaN/SiC) or ultra-wide bandgap (ex: AlGaN, Gallium oxide, AlN) device positioned above the heat spreader 26. HEMT devices and MMICs are examples, but any device operating near or above 1 kV, or at operational frequencies above several hundred GHz may be applicable. For example, bandgaps may be above 2 eV and up to, for example, 7 eV. In various embodiments the devices may have an energy density of greater than 2 W/mm. With improved thermal conductivity, the inventors believe it is possible to achieve operation of devices having significantly increased energy density of up to 20 W/mm or even 40 W/mm.

FIG. 2C schematically shows a top view of the heat generating portion 20 having multiple semiconductor devices 10 in accordance with illustrative embodiments. Certain figures may illustrate only a single semiconductor device 10, such as a transistor, for the purpose of simplifying the drawing and clearly explaining the interaction between components. It should be understood, however, that in practical implementations, the semiconductor device layer may include millions or even billions of densely packed transistors 10 and other active components 10, depending on the application and chip architecture. FIG. 2C shows a plurality of semiconductor devices 10 to better convey the concept of the heat-generating footprint 30, including how heat-producing elements 10 are distributed across a defined area. While the number of devices 10 illustrated is far fewer than would be present in a real-world implementation, the depicted arrangement is intended to help visualize the concept of dense device integration and the continuous thermal zone that is addressed by the heat spreader layer 26. The illustrative quantity and spacing of devices 10 in the figures should therefore be understood as schematic and non-limiting.

As shown in FIG. 2C, in some embodiments, the top surface 27 area of the carbon-12 enriched heat spreader layer 26 is dimensioned to match or exceed the area over which heat is generated by the semiconductor device layer. In this example, the length of the heat generating area 20 can be said to have an area roughly defined by a length 11 and a width 13. The area of the heat spreader 26, defined by the length 21 and the width 23, may match or exceed the area of the heat-generating footprint 30

Because modern integrated circuits often include billions of densely packed transistors and other active components, these generate heat over a tightly packed region of the chip. For thermal management purposes, it is not always practical to calculate the precise combined surface area of the individual heat-generating elements. Instead, in many implementations, the heat-generating region is characterized by a total footprint 30 or continuous perimeter that encloses the active device array. This area defined by the perimeter 30 provides a practical and functionally meaningful estimate of the thermal region to be covered by the C-12 layer.

FIG. 2C shows a dashed-line box drawn around the semiconductor devices 10 to illustrate the approximate location of the heat-generating footprint 30. While the box 30 may not precisely correspond to the exact locations of all individual transistors or active regions, it is intended to generally indicate the area over which heat is generated during device operation. This region is typically well understood during chip design and layout, and serves as a practical basis for sizing the carbon-12 heat spreader layer 26.

The heat-generating footprint 30 refers to the planar surface area on or within a semiconductor device structure over which thermal energy is produced during operation. This area typically encompasses the collective lateral extent of transistors, diodes, interconnects, and other active circuit elements that dissipate power as heat. In practice, the heat-generating footprint 30 may be defined by a continuous perimeter or bounding shape that encloses all such heat-generating components 10, including densely packed arrays of devices with minimal spacing. Because the spacing between individual devices 10 is often small relative to the device size (e.g., sub-micron), the entire enclosed region may be treated as a single continuous thermal zone for purposes of thermal design and heat spreading.

The heat-generating footprint 30 may also be characterized based on known design dimensions of the semiconductor die or chip, especially when detailed device-level mapping is impractical. This area serves as the reference region over which a heat spreader layer 26—such as a carbon-12 enriched diamond layer-should be positioned or sized in order to effectively collect and redistribute thermal energy.

The carbon-12 heat spreader layer 26 is typically deposited or bonded as a continuous, uninterrupted layer. Due to the nature of CVD growth or wafer-scale bonding, it is difficult to confine deposition to isolated local regions or individual hotspots. Therefore, in most embodiments, the heat spreader 26 is a monolithic layer that underlies the entire active region of the device chip and extends beyond it in some cases.

To function effectively, the C-12 heat spreader layer 26 should preferably have a surface area 32 that is at least equal to the area defined by the perimeter 30 enclosing the heat-generating semiconductor structures. In some embodiments, the heat spreader layer 26 has a top surface area 32 that is no smaller than 70% of the heat-generating area 30, more preferably at least 85%, and most preferably greater than or equal to 95%, in order to ensure adequate lateral phonon transport and efficient heat redistribution.

In other embodiments, the C-12 layer may be larger than the defined thermal perimeter, in order to provide thermal margin or to simplify manufacturing. However, because isotopically enriched carbon-12 material is expensive, unnecessarily large C-12 layers may increase cost without proportional thermal benefit. Therefore, in some embodiments, the surface area 32 of the C-12 layer is no more than 150%, or no more than 125%, of the area defined by the heat-generating device perimeter 30. This maintains a practical trade-off between thermal effectiveness and material cost.

The C-12 heat spreader layer 26 may also be dimensioned in reference to the continuous area of the overlying heat-generating semiconductor region, rather than a sum of individual device elements. Because of the extreme density of modern transistors and the minimal spacing between them, treating the device layer as a continuous thermal source simplifies the design and ensures that heat from all active regions is effectively intercepted by the spreader layer.

In one example, a high-power semiconductor device, such as a GaN-based RF amplifier or processor die, may have a heat-generating footprint 30 defined by a continuous region measuring 10 millimeters by 10 millimeters, resulting in a total active thermal area of 100 mm². This footprint 30 corresponds to the lateral dimensions of the semiconductor die or the portion of the die containing densely packed, heat-generating circuit elements such as transistors and interconnects.

To effectively spread heat laterally from this footprint 30, the carbon-12 enriched diamond heat spreader layer 26 is preferably fabricated with a top surface area 32 equal to or greater than the heat-generating footprint 30. In some embodiments, the C-12 layer has a surface area that closely matches the device area, such as 10 mm×10 mm (100 mm²). In other embodiments, the spreader 26 may extend slightly beyond the perimeter 30 of the active region—for example, 11 mm×11 mm (121 mm²)—to provide margin for alignment tolerance or enhanced lateral thermal conduction.

To avoid unnecessary cost due to the use of isotopically enriched material, the C-12 layer 26 is preferably not substantially larger than required. For example, in certain cost-sensitive embodiments, the surface area 32 of the C-12 layer may be constrained to no more than 125% of the heat-generating footprint 30 (e.g., 125 mm² in this example), and more preferably no more than 110-115%, to balance thermal performance and material efficiency.

In contrast, an undersized C-12 layer 26—such as one measuring 8 mm×8 mm (64 mm²)—would cover only 64% of the heat-generating area 30, which may result in incomplete heat interception and non-uniform thermal gradients across the device surface. Accordingly, the heat spreader layer 26 in some embodiments is sized to provide at least 85-95% coverage of the heat-generating footprint 30, and may have full or slightly extended coverage for optimal thermal management.

Although in some illustrations the diamond thermal sink layer 24 is shown as having a significantly larger area (defined by the length 31 and the width 33) than the overlying heat spreader layer 26, it should be understood that in other embodiments, the thermal sink and heat spreader layer 26s may have substantially the same lateral dimensions.

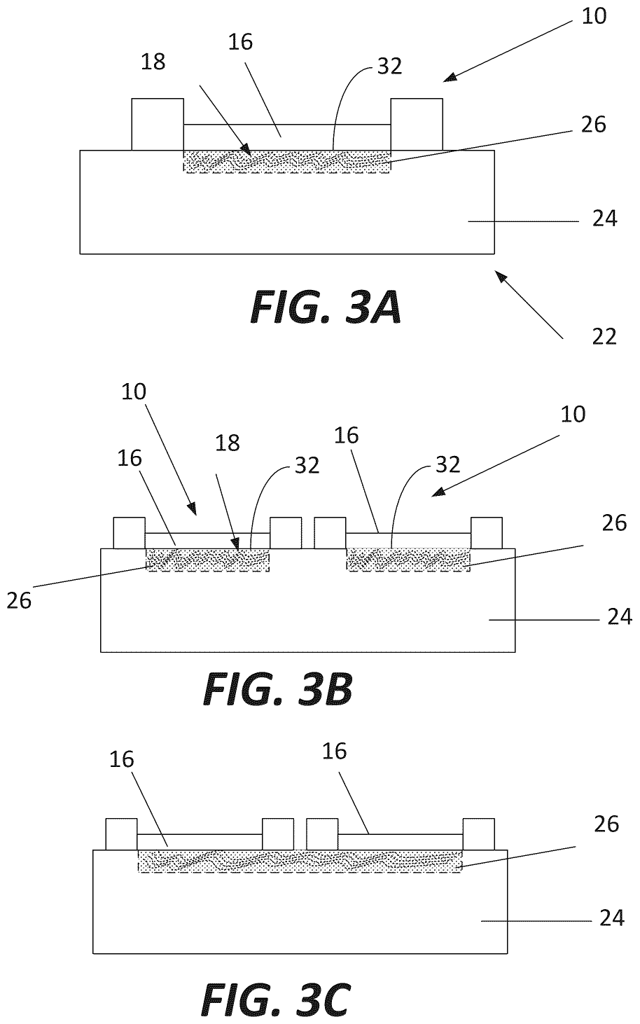

FIG. 3A schematically shows a heat spreading portion 26 having a top surface area 32 that is substantially the same as the size of the perimeter 30 (e.g., the area of the gate 16) in accordance with illustrative embodiments. In various embodiments, the heat spreading portion 26 may have the surface area 32 that is the same as, greater than, or less than, the area 30 of the heat generating component (e.g., the size of the gate 16 of the transistor).

FIG. 3B-3C schematically show a plurality of devices on a single substrate 22 in accordance with illustrative embodiments. As mentioned previously, a single device 10 was shown for discussion purposes. However, illustrative embodiments may have may a great number of devices thereon. FIGS. 3B-3C schematically show two devices 10. The heat spreading portion 26 may be patterned to match the gate 16 size (e.g., as shown in FIG. 3B) and minimize total surface area of the heat spreading portion 26. As shown in FIG. 3B, various embodiments may have a plurality of heat spreading portions 26. Additionally, or alternatively, as shown in FIG. 3C, a single heat spreading portion 26 may cover a plurality of devices having heat generating portions 20.

In some embodiments, the heat spreading layer 26 may comprise a plurality of discrete heat spreading portions 26, each corresponding to a localized region of the underlying or overlying heat-generating semiconductor devices 10. These multiple heat spreading portions 26 may be spatially separated, but collectively cover the heat-generating footprint 30 or a substantial portion thereof. The total surface area 32 of the plurality of heat spreading portions 26 may, in some cases, be equal to or greater than the area defined by the heat-generating footprint 30.

In alternative embodiments, one or more heat spreading portions may be positioned to cover only selected subregions of the heat-generating footprint—for example, those corresponding to known hotspots or clusters of high-power devices. These partial coverage configurations may be employed to optimize material usage, reduce cost, or target thermal management to critical regions, provided sufficient lateral thermal spreading is maintained for effective operation.

In various embodiments, the devices described herein may be transistors, among other things. Additionally, in some embodiments, the devices may be formed by doped junctions. In various embodiments, the devices may have a high energy density (e.g., an energy density that is greater than 5 W/mm).

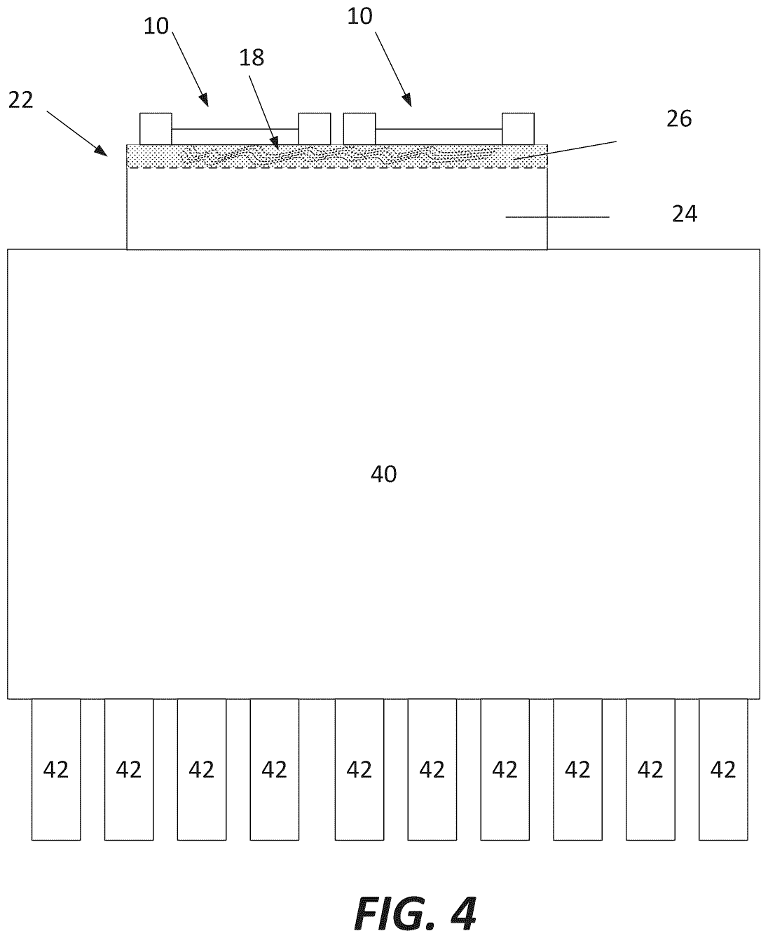

FIG. 4 schematically shows the integrated device coupled to a large system level heat sink 40 (e.g., a non-diamond heat sink 40) in accordance with illustrative embodiments. The non-diamond heat sink 40 may be formed from, for example, copper, aluminum, silver, nickel, iron, zinc, and combinations thereof. The large heat sink 40 may include fins 42, among other things. In general, the non-diamond heat sink 40 may be larger than the diamond heat sink 24.

It should be understood that the diamond thermal sink layer 24 refers to a micro-scale, material-integrated layer that resides beneath the carbon-12 enriched heat spreader 26 and forms part of the thermal substrate 22. This layer, which may be formed from standard-isotopic or lightly enriched diamond, provides intermediate thermal conduction, channeling heat away from the spreader layer 26 toward an underlying cooling structure 40. In various embodiments, thermal sink layer 24 is a structural component of the device-level substrate 22 and may be fabricated monolithically or as part of a composite diamond body.

By contrast, the term system-level heat sink 24 refers to a macro-scale, package-level cooling structure, typically composed of high thermal conductivity metals such as copper or copper alloys, and often incorporating water channels, fins, or vapor chambers. The system-level heat sink 24 is mounted beneath the diamond substrate 22 and functions as the final stage of heat extraction, removing accumulated thermal energy from the device into the ambient environment or liquid coolant system.

Thus, the diamond thermal sink layer acts as a high-conductivity intermediate layer e.g., conducting heat from the semiconductor interface (via the C-12 spreader) toward the system-level heat sink 24. The two sinks operate in thermal sequence: the diamond layer handles in-package conduction, while the system-level heat sink 24 enables external dissipation to the environment.

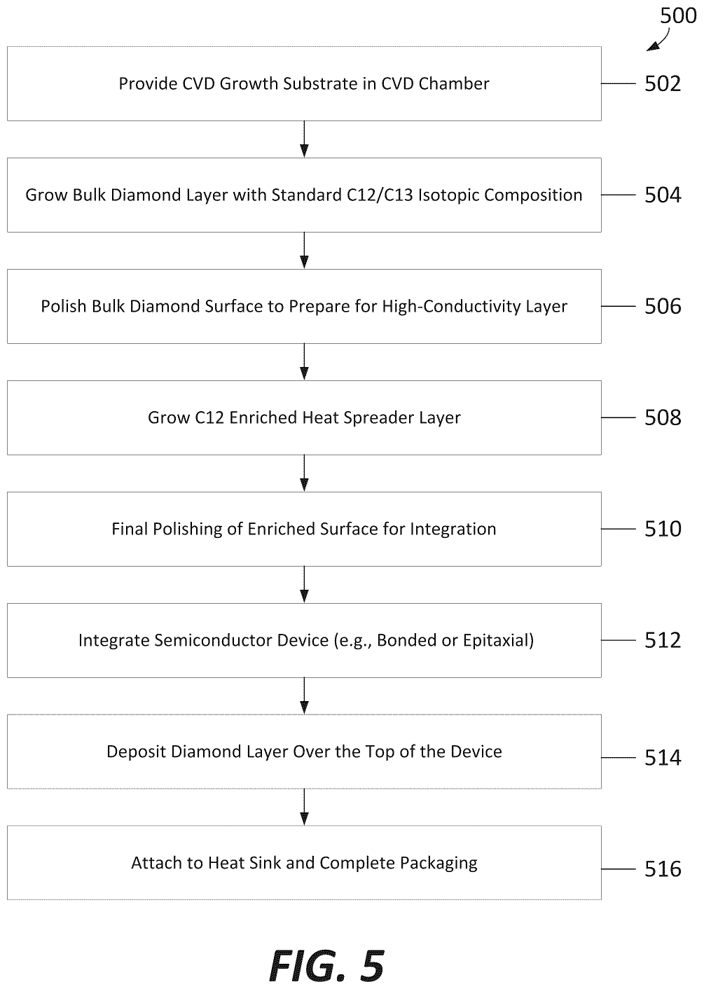

FIG. 5 shows a process of fabricating a diamond-based heat spreading substrate 22 in accordance with illustrative embodiments of the invention. It should be noted that this method is substantially simplified from a longer process that may normally be used. Accordingly, the method shown in FIG. 5 may have many other steps that those skilled in the art likely would use. In addition, some of the steps may be performed in a different order than that shown, or at the same time. Furthermore, some of these steps may be optional in some embodiments. Accordingly, the process 500 is merely exemplary of one process in accordance with illustrative embodiments of the invention. Those skilled in the art therefore can modify the process as appropriate.

The process begins at step 502 by providing a CVD growth substrate in a CVD chamber. It should be understood that the CVD growth substrate is not the same as bulk grown substrate 22 shown in FIGS. 1-4. As used herein, the term grown diamond substrate 22 refers to the diamond material grown during the chemical vapor deposition (CVD) process, which may include one or more isotopically distinct regions. In certain embodiments, the bulk grown substrate 22 comprises both a surface region enriched in carbon-12 (the heat spreader layer 26) and an underlying region of standard isotopic composition (the thermal sink layer 24). These layers may be grown sequentially in a single CVD run or in separate steps, and together they form a monolithic diamond body.

The CVD growth substrate by contrast, refers to the initial base substrate—such as single-crystal diamond, polycrystalline diamond, silicon, sapphire, or silicon carbide—upon which the bulk diamond material is deposited. The CVD growth substrate may be removed after growth (e.g., by wafer separation) or may be retained depending on the intended final structure. It generally does not form part of the thermal management function of the final device.

This CVD growth substrate may be a single-crystal diamond, polycrystalline diamond (e.g., ultrananocrystalline), or a heteroepitaxial platform like silicon or sapphire. The substrate is preferably compatible with high-temperature CVD conditions and allows diamond nucleation. This initial substrate serves as the growth base for the bulk diamond structure and may be later removed, reused, or remain as part of the final thermal structure.

In embodiments where polycrystalline diamond is used as the growth substrate or thermal support layer, the domain size of the individual crystallites is selected to optimize thermal transport. Preferably, the polycrystalline diamond comprises ultra-nanocrystalline or nanocrystalline diamond having domain sizes smaller than one-quarter of the phonon wavelength, thereby minimizing phonon scattering and restoring effective thermal conductivity. In alternative embodiments, the polycrystalline layer may comprise large domains, such that phonon scattering is negligible due to the limited number of boundary interfaces encountered. Polycrystalline structures with intermediate domain sizes may exhibit reduced thermal performance and are generally avoided in high-conductivity applications.

At step 504, the process grows a bulk diamond thermal sink layer 24. Using CVD, a thick layer of diamond is grown from natural-abundance methane gas or methane gas without isotopic enrichment. This layer contains a mix of carbon-12 and carbon-13 isotopes and provides structural rigidity and vertical thermal transport. It forms the body of the thermal substrate 22 and is grown to a thickness sufficient for heat conduction and mechanical stability—typically in the hundreds of microns range.

In CVD-based diamond growth, the isotopic composition of the deposited diamond is determined substantially entirely by the isotopic composition of the carbon-containing precursor gas. Accordingly, the use of methane gas enriched in carbon-12 enables deposition of a diamond layer that is correspondingly enriched in carbon-12, while deposition from methane with standard commercial isotopic composition produces a diamond layer with a natural or unenriched carbon-12 to carbon-13 ratio. Illustrative embodiments use this relationship to selectively form isotopically enriched surface layers for thermal spreading, while using unenriched gas for the bulk portion of the substrate 22 to reduce material costs.

The thermal sink layer 24 is preferably non-pure or non-enhanced isotopic composition. In some embodiments, the thermal sink layer 24 may contain modest isotopic enrichment relative to non-isotopically enriched commercially available methane, so long as the carbon-12 concentration remains lower than that of the overlying heat spreader layer 26. This relative isotopic contrast is sufficient to maintain a functional thermal gradient and preserve the performance benefits of the enriched surface region.

In various embodiments, the non-enriched diamond or the diamond thermal sink layer 24 is formed from diamond material that is not isotopically enriched in carbon-12 relative to commercially available carbon sources. In some embodiments, this sink layer 24 may be formed using chemical vapor deposition (CVD) from methane gas having a natural or unenriched isotopic composition (e.g., approximately 98.9% carbon-12 and 1.1% carbon-13). However, various embodiments are not limited to any specific method of formation, and the diamond thermal sink layer 24 may also be formed by other deposition methods, including physical vapor deposition (PVD), high-pressure high-temperature (HPHT) synthesis, heteroepitaxial seeding and growth on non-diamond growth substrates. Additionally, the thermal sink layer 24 may comprise polycrystalline, nanocrystalline, or single-crystal diamond, provided that its thermal conductivity and structural properties are suitable for supporting heat dissipation from the heat spreader layer 26. The isotopic composition of the thermal sink layer 24 may vary and may include small amounts of isotopic enrichment or depletion, so long as it is less enriched than the overlying heat spreader layer 26 and does not materially alter the intended thermal gradient or functional distinction between the two regions.

In some embodiments, the thermal sink layer 24 may contain modest isotopic enrichment relative to commercially available methane, so long as the carbon-12 concentration remains significantly lower than that of the overlying heat spreader layer 26. This relative isotopic contrast is sufficient to maintain a functional thermal gradient and preserve the performance benefits of the enriched surface region.

CVD diamond growth involves dissociating a carbon-containing gas (e.g., methane, CH₄) in a plasma or thermal environment, where carbon atoms (C) are extracted from the gas. These atoms then incorporate directly into the growing diamond lattice on the substrate. Because this is a direct atom-by-atom deposition process, the isotopic distribution of carbon in the gas—specifically the ratio of C-12 to C-13—is preserved in the solid film. There is no significant fractionation or separation of isotopes during CVD diamond growth.

Illustrative embodiments input gas with 99.99% C12, and the deposited diamond layer has nearly the same isotopic composition. The carbon isotope ratio in the deposited diamond (solid phase) very closely reflects the carbon isotope ratio in the precursor gas (gas phase), with variations typically within ±0.05% to ±0.1%., depending on the system and measurement method.

In various embodiments, the carbon-12 enriched heat spreader layer 26 may be deposited using isotopically enriched methane (¹²CH₄), wherein the methane contains greater than or equal to 99.5%, 99.9%, or 99.99% carbon-12 by atomic percentage. It is theorized, but the inventor has not confirmed, that alternative carbon-12 enriched precursors may include isotopically enriched acetylene or ethylene, provided they are compatible with the CVD growth system.

In some embodiments, the thermal sink layer 24 may be include or be completely formed from a material other than diamond. Suitable materials may include, but are not limited to, silicon carbide, aluminum nitride, beryllium oxide, copper, gallium nitride, or composite materials incorporating diamond particles or metal matrices.

The heat spreader layer 26 may be deposited directly on the thermally conductive material where compatible with chemical vapor deposition, or alternatively may be formed separately and bonded to the thermal support structure using thermal compression bonding, diffusion bonding, or adhesive interfaces. The use of non-diamond thermal sink layers may be desirable in applications requiring electrical insulation, mechanical compliance, cost optimization, or compatibility with existing thermal management systems.

At step 506, the bulk diamond surface 24 is polished to prepare for the high-thermal conductivity diamond layer 26. After the bulk diamond 24 is grown, the top surface is polished to achieve a relatively flat and uniform surface. This prepares it for deposition of the isotopically enriched carbon-12 layer 26. While this polishing does not require ultra-high smoothness, it must reduce surface roughness enough to ensure uniformity and minimal overuse of expensive C-12 material in the next step.

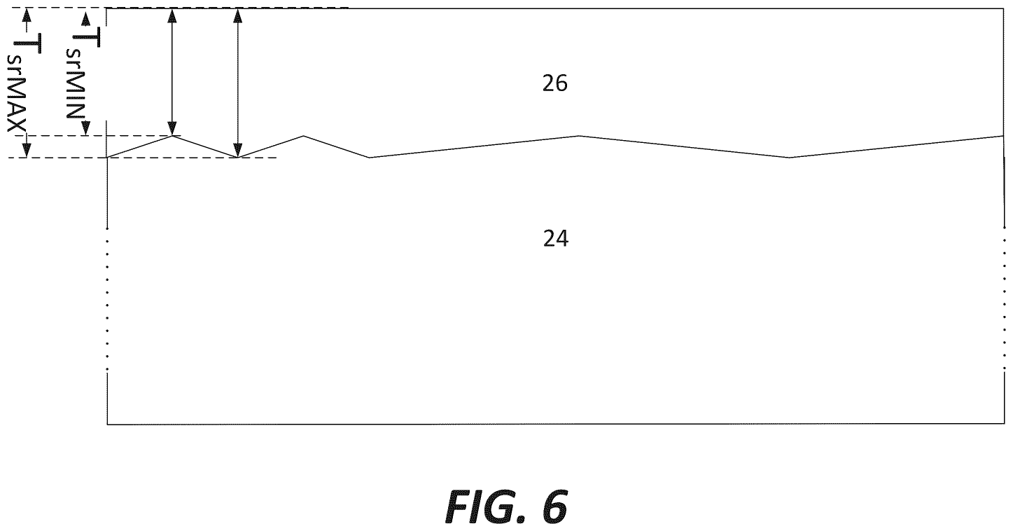

The top of the bulk layer 24 is then rough-polished to create a surface that is flat enough for the next stage of growth. At this point, ultra-fine polishing is not necessary, as the goal is not to prepare for device bonding yet, but to control the interface thickness for the next layer. The polishing does, however, influence the minimum and maximum thickness of the subsequent C-12 enriched layer 26. Because the interface between the bulk layer 24 and the enriched layer 26 is slightly uneven due to the rough polishing, the C-12 layer thickness varies locally, as shown in FIG. 6. In various embodiments, the minimum thickness of the C-12 layer is sufficiently thick to spread heat laterally (e.g., T_{srMIN}). Extra thickness in valleys is not harmful but can increase material cost (e.g., T_{srMAX}).

The surface of the diamond thermal sink layer 24 is polished to a roughness less than 10 nanometers root mean square (RMS), ensuring sufficient smoothness for deposition of the isotopically enriched heat spreader layer 26. Surface roughness measurements may be performed using atomic force microscopy (AFM) or white-light interferometry. In some embodiments, the polished surface of the diamond sink layer 24 exhibits an RMS surface roughness of less than 10 nanometers, and in certain embodiments, less than 2 nanometers, as determined over a representative surface area of at least 10 μm×10 μm.

At step 508, the C12 enriched heat spreader layer 26 is grown. The heat spreader layer 26 may be formed from isotopically enriched carbon-12 (also referred to as C12 pure). The heat spreader layer 26 is formed from carbon-containing material having a greater proportion of carbon-12 (C-12) than that found in standard or commercially available methane gas, which typically contains approximately 98.9% carbon-12 and 1.1% carbon-13 (C-13). In some embodiments, the enriched material may contain greater than 99.5%, 99.9%, or even 99.99% carbon-12 by atomic percentage. It is understood, however, that complete exclusion of carbon-13 is not required for the thermal conductivity benefits described herein, and that trace amounts of carbon-13 may be present without departing from the scope of the invention.

With the base diamond polished, the substrate 22 is reintroduced into the CVD chamber and a thin layer of highly enriched carbon-12 diamond is grown using isotopically purified methane gas. This top layer functions as an ultra-efficient in-plane heat spreader 26, redistributing thermal energy away from localized hotspots in the attached semiconductor. The use of C-12 pure diamond in this surface region reduces costs while achieving superior performance.

The diamond wafer is returned to the CVD chamber, and high-purity carbon-12 methane gas is introduced to grow a thin top layer. This C-12 enriched diamond layer has dramatically higher thermal conductivity (up to ˜3000 W/m·K compared to ˜2200 W/m·K for diamond of standard isotopic composition.) and acts as an in-plane heat spreader 26 for semiconductor devices. The thickness is carefully controlled to provide adequate thermal spreading, while minimizing the use of expensive enriched gas.

For the non-enriched thermal sink layer 24, methane gas with unenriched, unpure, or natural C12 isotopic abundance (approximately 98.9% C12 and 1.1% C13) may be used. Other standard hydrocarbons such as acetylene, ethylene, or ethanol may also be employed. In all embodiments, the precursor gas composition directly determines the isotopic ratio of the resulting diamond, and transitions between layers may be performed by switching gas sources within the same deposition process.

Full enrichment of the entire diamond wafer may be prohibitively expensive. By localizing the enrichment to just a few microns at the surface, the process achieves nearly the same thermal benefit with dramatic cost reduction.

In some embodiments, the heat spreader layer 26 comprises a minimum thickness sufficient to enable lateral phonon-based thermal transport across the surface area of the underlying semiconductor device. The minimum thickness may depend on the device footprint 30, surface roughness of the underlying thermal sink layer 24, and the desired thermal spreading efficiency. If the layer 26 is too thin, phonon scattering at interfaces or thickness non-uniformity may reduce the effective lateral thermal conductivity. Accordingly, the heat spreader layer 26 is preferably formed with a thickness of at least 1 micron, and more preferably 5-20 microns, to ensure consistent heat redistribution from localized thermal hotspots into the broader diamond thermal sink layer 24.

In various embodiments, the enriched carbon-12 layer is not intended to serve as a bulk heat sink 24, but rather as a heat spreader 26. By redistributing thermal energy laterally from localized hotspots at the device interface, this layer increases the effective surface area from which heat may be extracted, thereby improving overall thermal performance. Accordingly, in various embodiments, a bottom surface area of the C12 layer is configured to be greater than the footprint 30 of the semiconductor devices.

At step 510, the enriched surface 32 of the heat spreader layer 26 is polished for integration. After C-12 growth, the surface 32 is polished to a very high flatness and low roughness to support downstream integration. This is especially important for wafer bonding or epitaxial deposition of high-bandgap semiconductors, as surface smoothness influences both thermal interface resistance and mechanical integrity.

This enriched layer 26 is then precision polished to achieve ultra-low surface roughness suitable for device integration. This enables subsequent wafer bonding with a thinned semiconductor layer, or epitaxial growth of a semiconductor layer directly on the diamond. Surface roughness at this stage is preferably controlled at the nanometer scale to ensure thermal contact quality and mechanical stability.

In various embodiments where epitaxial growth of a semiconductor device layer is desired, the isotopically enriched surface may be polished to a quality suitable for heteroepitaxy or homoepitaxy. This is particularly relevant for diamond-on-diamond structures or when using lattice-compatible wide bandgap semiconductors. Appropriate surface preparation ensures sufficient lattice alignment and interface quality for defect-minimized growth.

In some embodiments, the surface of the isotopically enriched diamond heat spreader layer 26 is polished to an RMS roughness of less than 0.5 nanometers, and preferably less than 0.2 nanometers, over a measurement area of at least 10 μm×10 μm, to support subsequent epitaxial growth of single-crystal semiconductor layers. Such surface quality facilitates lattice-matched epitaxy, reduces interfacial defect density, and ensures strong thermal and mechanical coupling between layers.

At step 512, the semiconductor device 10 is integrated (e.g., bonded or epitaxially deposited). A thinned semiconductor device 10 wafer—such as GaN, SiC, GaAs, or doped diamond—is either bonded to the C-12 diamond surface or directly grown (epitaxially) on it, depending on lattice matching and device requirements. Bonding is more typical for mismatched materials, where the device wafer is thinned after fabrication and then thermally and mechanically attached to the diamond layer for heat dissipation.

There are two primary integration options. A first option is wafer bonding, where a semiconductor device (e.g., GaN, SiC, GaAs, or doped diamond) is fabricated on another wafer, thinned to reduce thermal resistance, and then bonded to the polished C-12 surface. This is the most common path when using materials that cannot be epitaxially grown on diamond.

Some embodiments use epitaxial growth, particularly when using diamond-on-diamond or wide-bandgap semiconductors—the device layer may be directly grown on the polished C-12 layer. This requires epitaxial matching, which may be more feasible with doped diamond or specially prepared interfaces.

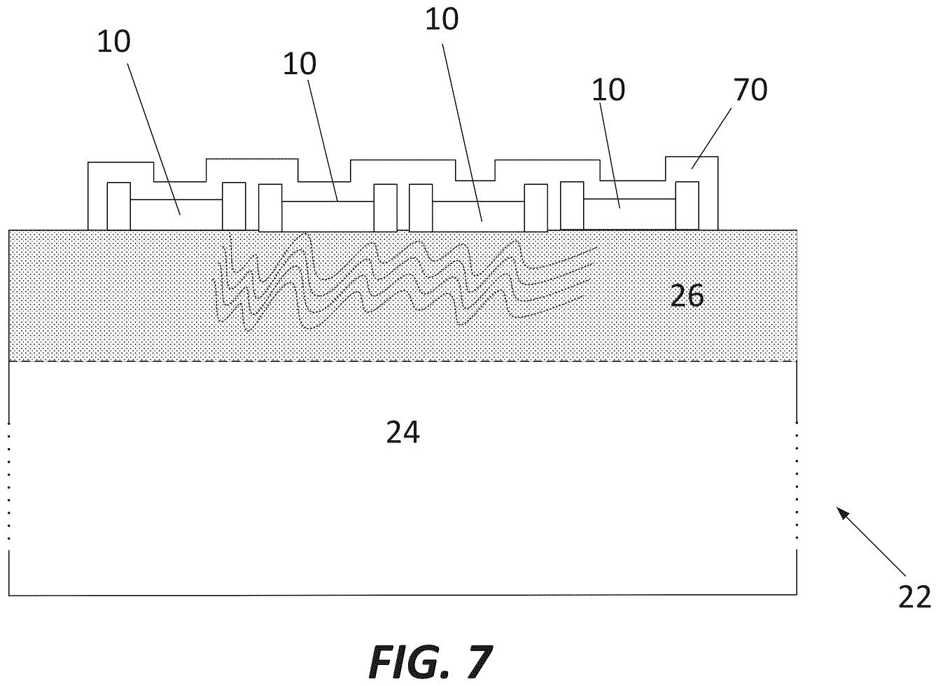

At step 514, the process deposits a top diamond layer 70 over the top surface of the device (as shown in FIG. 7). The additional diamond layer 70—potentially isotopically enriched with carbon-12—is deposited over the top side of the semiconductor device. This top-side diamond layer 70 acts as a secondary heat spreader 26, distributing thermal energy from the front surface of the chip. It allows for dual-sided heat dissipation, where heat flows both downward through the substrate 22 and upward into the packaging or ambient, significantly improving thermal performance in high-power or high-density device configurations. This top-side diamond advantageously functions as an additional heat spreader, drawing heat upward as well as downward. This layer may also be C-12 enriched, depending on thermal design and cost constraints. Advantageously, this layer 70 improves dual-sided heat dissipation, which is especially beneficial in high-power applications. This layer may be grown after dicing or selectively deposited depending on package configuration.

At step 516, a system level heat sink 24 is attached and the packaging is completed.

The entire assembly may be mounted onto the system-level heat sink 40, typically a copper structure, optionally with water cooling or embedded thermal channels. Additional packaging steps such as device dicing, electrical interconnect formation, and encapsulation may be performed depending on the specific application. The dual-sided diamond heat spreader 26 ensures optimal thermal management, enabling enhanced reliability and performance for next-generation semiconductor systems.

The completed structure—now including the diamond thermal substrate 22 and semiconductor device—is mounted onto a macroscale heat sink 24, typically copper or water-cooled copper with embedded channels. This removes heat that has been spread by the C-12 layer 26 and transported through the bulk diamond 24. Additional steps such as device dicing, wire bonding, interconnect formation, and encapsulation are carried out based on final product requirements.

These thermally optimized diamond structures are particularly well-suited for use in high-power RF amplifiers, power electronics, and optoelectronic systems where thermal bottlenecks currently limit device scaling and efficiency. The described embodiments offer scalable, high-performance platforms for next-generation device packaging and integration.

The process then comes to an end.

As described earlier, this process 500 may be modified in various ways. For example, some steps, such as step 514, are optional. Furthermore, in some embodiments, step 514 may take place before step 512. Some steps may be reversed or omitted. For example, some embodiments may reverse the order of steps 504 and 508.

In some embodiments, the sequence of diamond layer deposition may be reversed to streamline fabrication and reduce polishing steps. This “reverse process” involves first depositing the carbon-12 enriched heat spreader layer 26 onto the growth substrate from step 502, and subsequently growing the bulk diamond thermal sink layer 24 on top of the heat spreader layer 26. The entire diamond structure may then be separated from the growth substrate and inverted, such that the enriched C-12 layer 24 is ultimately positioned at the top, ready to receive a semiconductor device 10 or epitaxial layer.

For the above-described “reverse process”—wherein the isotopically enriched carbon-12 layer 26 is deposited before the non-enriched diamond thermal sink layer24—the surface quality of the initial CVD growth substrate defines the interface and eventual top surface of the C-12 layer after wafer separation and inversion. Accordingly, the initial substrate is preferably polished to a high degree of flatness and smoothness, with a surface roughness of less than 2 nanometers RMS, and more preferably less than 0.5 nanometers RMS, to support the growth of a high-quality, thermally and mechanically continuous C-12 layer 26. This polishing ensures that the C-12 surface 32—after flipping—is suitable for direct semiconductor bonding or epitaxial growth without requiring further post-processing.

The reverse process introduces an isotopically enriched carbon-12 precursor gas into the CVD chamber and depositing a thin, high-thermal-conductivity diamond layer. After the desired thickness is achieved, the gas source is switched-without breaking vacuum—to a non-enriched methane gas (e.g., standard commercial methane containing approximately 98.9% C12 and 1.1% C13). This allows for seamless continuation of growth, enabling a thick, cost-effective bulk diamond layer to be formed atop the C-12 enriched region.

The transition between the two layers—C-12 and C12/C13—is thus formed as a chemically continuous interface, without the need for polishing, reloading, or additional surface activation between depositions. This configuration minimizes potential sources of interfacial contamination, crystal mismatch, or mechanical delamination, which can occur in multi-step deposition or bonding processes.

After growth is complete, the stack is separated from the original growth substrate using one of several wafer separation techniques, such as laser cleaving, ion implantation, or a sacrificial interlayer process. The separated diamond structure is then flipped, so that the originally deposited carbon-12 enriched layer becomes the topmost surface of the final composite. This exposed enriched surface may then be polished (if needed) and bonded to a semiconductor device or used as an epitaxial substrate 22.

This reverse growth architecture offers several benefits, including:
Elimination of the intermediate polishing step required between the bulk and enriched layers in the forward-growth process.
Preservation of a clean, atomically continuous CVD interface between layers.
Reduction in total process complexity and cycle time.
Efficient use of high-cost enriched precursor gases, localized only at the start of growth.
Greater flexibility in layer thickness control and thermal gradient design.

Accordingly, the reverse growth method represents a robust and cost-efficient manufacturing approach for producing layered diamond substrates 22 with optimized isotopic profiles for thermal management applications.

Additionally, various embodiments may include intermediate steps not described here. For example, In some embodiments, after the diamond material stack has been grown—including both the bulk diamond layer having natural isotopic composition and the isotopically enriched carbon-12 (C-12) surface layer—a wafer separation process may be employed to detach the diamond film from the original growth substrate. The growth substrate may be single-crystal diamond, polycrystalline diamond, or a heteroepitaxial material such as silicon, sapphire, or silicon carbide, and may or may not be retained in the final product. Wafer separation serves several purposes, including enabling reuse of the growth substrate, exposing a specific layer (such as the C-12 enriched surface) for subsequent device integration, or producing a freestanding diamond wafer with a defined thickness and thermal profile.

Several techniques may be used to achieve wafer separation. In one approach, a laser cleaving process is utilized wherein a focused laser beam is directed beneath the surface of the diamond stack to locally graphitize a sub-surface layer. This graphitized region forms a mechanical plane of weakness that enables the overlying diamond layer to be separated cleanly from the growth substrate, either mechanically or chemically. In another approach, ion implantation is employed, such as by implanting hydrogen ions at a specified depth within the growth substrate. Subsequent annealing or etching causes graphitization or void formation in the implanted layer, enabling controlled separation at that depth. This method is commonly used in the industry and is protected by patents that may expire in the near future, potentially allowing broader adoption. Alternatively, a sacrificial intermediate layer may be introduced during the deposition process—such as a non-diamond layer that is chemically or thermally etchable—so that the grown diamond film can be released from the underlying CVD growth substrate following growth.

Wafer separation may be performed before or after the precision polishing of the C-12 enriched layer 26, depending on the chosen manufacturing flow. In embodiments where the isotopically enriched layer 26 is grown first, followed by the bulk diamond 24, wafer separation allows the structure to be flipped, positioning the high-conductivity C-12 layer 26 at the top surface for direct contact with a semiconductor device. This inverted structure avoids the need for a second growth and polishing step, potentially simplifying the process. Additionally, because the growth substrate is typically high-value material, enabling its reuse through clean separation is highly desirable for cost-effective manufacturing. These wafer separation techniques support the scalable production of high-performance, thermally optimized diamond substrates 22 with isotopically engineered heat-spreading layers.

In various embodiments, the process of FIG. 5 may be completed by multiple different parties. For example, some embodiments produce a diamond substrate 22 having a bulk region 24 formed from isotopically standard carbon and a top surface region 26 enriched in carbon-12. The enriched surface layer 26 functions as a high-performance lateral heat spreader 26 for semiconductor integration. In typical use cases, a device manufacturer would then bond a thinned semiconductor wafer containing active devices to the C-12 enriched surface 32, enabling efficient dissipation of heat from localized hotspots into the underlying diamond and ultimately to a system-level heat sink 40. The combination of thermal performance and cost efficiency makes this component well-suited for commercial sale and industrial integration.

As used in this specification and the claims, the singular forms “a,” “an,” and “the” refer to plural referents unless the context clearly dictates otherwise. For example, reference to “the integrated circuit” in the singular includes a plurality of integrated circuits, and reference to “the device” in the singular includes one or more devices and equivalents known to those skilled in the art. Thus, in various embodiments, any reference to the singular includes a plurality, and any reference to more than one component can include the singular.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein.

It is, therefore, to be understood that the foregoing embodiments are presented by way of example only and that, within the scope of the appended claims and equivalents thereto, inventive embodiments may be practiced otherwise than as specifically described and claimed. Illustrative embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure. Disclosed embodiments, or portions thereof, may be combined in ways not listed above and/or not explicitly claimed. Thus, one or more features from variously disclosed examples and embodiments may be combined in various ways. For example, it is to be understood that the present disclosure contemplates that, to the extent possible, one or more features of any embodiment can be combined with one or more features of any other embodiment.

Various inventive concepts may be embodied as one or more methods, of which examples have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Although the above discussion discloses various exemplary embodiments of the invention, it should be apparent that those skilled in the art can make various modifications that will achieve some of the advantages of the invention without departing from the true scope of the invention.

What is claimed is:

1. A diamond structure comprising:
a diamond heat spreader layer comprising diamond enriched in carbon-12;
and a diamond thermal sink layer disposed beneath the heat spreader layer, the thermal sink layer comprising diamond having a non-enriched isotopic composition.

2. The composite diamond structure of claim 1, wherein the carbon-12 atomic concentration in the heat spreader layer is equal to exceeds 99.5%.

3. The composite diamond structure of claim 1, wherein the heat spreader layer has a thickness between 1 micron and 20 microns.

4. The composite diamond structure of claim 1, wherein the thermal sink layer comprises diamond with a carbon-12 to carbon-13 isotopic ratio substantially equivalent to that of naturally occurring methane.

5. The composite diamond structure of claim 1, wherein the heat spreader layer and the thermal sink layer are formed in a continuous chemical vapor deposition process by switching from an isotopically enriched methane gas to a non-enriched methane gas without interrupting deposition.

6. The composite diamond structure of claim 1, wherein the structure is formed by growing the heat spreader layer on a polished substrate, subsequently growing the thermal sink layer on the heat spreader layer, and separating the grown structure from the substrate to expose the heat spreader layer at the top surface.

7. The composite diamond structure of claim 1, further comprising a wide bandgap or ultra-wide bandgap semiconductor device coupled to the heat spreader layer.

8. A method of fabricating a diamond thermal structure, comprising:
depositing a diamond heat spreader layer onto a substrate using a carbon-containing precursor gas that is isotopically enriched in carbon-12;
switching the precursor gas to a carbon-containing gas having a non-enriched isotopic composition;
depositing a diamond thermal sink layer onto the heat spreader layer using the non-enriched gas; and
separating the diamond thermal structure from the substrate to expose the heat spreader layer at a surface of the structure.

9. The method of claim 8, wherein the carbon-12 concentration in the isotopically enriched precursor gas is equal to or greater than 99.5%.

10. The method of claim 8, wherein the heat spreader layer is deposited to a thickness between 1 micron and 20 microns.

11. The method of claim 8, wherein depositing the diamond heat spreader layer and depositing the diamond thermal sink layer are performed in a continuous chemical vapor deposition (CVD) process without breaking vacuum.

12. The method of claim 8, wherein the substrate comprises single-crystal or polycrystalline diamond.

13. The method of claim 8, wherein separating the diamond thermal structure from the substrate comprises laser cleaving, ion implantation, or removal of a sacrificial release layer.

14. The method of claim 8, further comprising flipping the separated diamond thermal structure such that the isotopically enriched heat spreader layer is positioned at a top surface.

15. The method of claim 8, further comprising polishing the surface of the heat spreader layer to a surface roughness suitable for bonding to a semiconductor device.

16. A method of fabricating a diamond thermal structure, comprising:
depositing a diamond thermal sink layer onto a substrate using a carbon-containing precursor gas having a non-enriched isotopic composition;
polishing a surface of the diamond thermal sink layer to a degree sufficient for subsequent deposition;
depositing a diamond heat spreader layer onto the polished surface using a carbon-containing precursor gas that is isotopically enriched in carbon-12.

17. The method of claim 16, wherein the carbon-12 concentration in the isotopically enriched precursor gas is greater than 99%.

18. The method of claim 16, wherein the heat spreader layer has a thickness between 1 micron and 20 microns.

19. The method of claim 16, wherein both the thermal sink layer and the heat spreader layer are deposited using chemical vapor deposition (CVD).

20. The method of claim 16, wherein the polishing the surface of the diamond thermal sink layer produces a surface roughness less than 10 nanometers RMS.
